(19) United States
(12) Patent Application Publication
(10) Pub. No.: US 2026/0353862 A1
(43) Pub. Date: Nov. 5, 2026

(54) SEMICONDUCTOR STRUCTURE AND MANUFACTURING METHOD THEREOF

(71) Applicant: HON HAI PRECISION INDUSTRY CO., LTD., New Taipei City (TW)

(72) Inventors: Te-En TSENG, New Taipei City (TW); Wu-Cheng KUO, Hsinchu City (TW); Yun-Hung SHEN, Hsinchu City (TW)

(21) Appl. No.: 19/243,632

(22) Filed: Jun. 19, 2025

(30) Foreign Application Priority Data
Apr. 30, 2025 (TW) 114116243

(51) Int. Cl. H10H 20/01; H10H 20/851; H10H 20/855; H10H 20/857; H10W 90/00

(52) U.S. Cl. CPC H10H 20/018; H10H 20/8512; H10H 20/855; H10H 20/857; H10W 90/00

(57) ABSTRACT

A semiconductor device fabrication method includes: providing a light-emitting diode (LED) driver wafer; providing an LED wafer; and bonding the LED driver wafer and the LED wafer through hybrid bonding. The LED driver wafer includes: transistor devices; a first metal interlayer dielectric layer covering the transistor devices; and first bonding pads located within the first metal interlayer dielectric layer. The LED wafer includes: LED; a second metal interlayer dielectric layer covering the LED; and second bonding pads located within the second metal interlayer dielectric layer. The first bonding pads are bonded to the corresponding second bonding pads, and the first metal interlayer dielectric layer is bonded to the second metal interlayer dielectric layer.

### PRIORITY CLAIM AND CROSS-REFERENCE

The present application claims priority to Taiwan Application Serial Number 114116243, filed Apr. 30, 2025, which is herein incorporated by reference in its entirety.

### BACKGROUND

As the applications of Micro-LED technology continue to evolve, such as its use in AR glasses, the size and pitch requirements for Micro-LEDs are becoming increasingly smaller. Current mainstream methods for integrating Micro-LED chips with LED driver chips, such as mass transfer and thermocompression bonding, can no longer meet these demands. Therefore, new Micro-LED fabrication methods need to be developed to address these emerging requirements.

### SUMMARY

Embodiments of the present disclosure provide a method for forming a semiconductor device, comprising: transistor devices; a first inter-metal dielectric layer, covering the transistor devices; and first bonding pads in the first inter-metal dielectric layer; providing a light-emitting diode wafer, comprising: light-emitting diodes; a second inter-metal dielectric layer, covering the light-emitting diodes; and second bonding pads in the second inter-metal dielectric layer; and bonding the light-emitting diode driver wafer to the light-emitting diode wafer through hybrid bonding, wherein the first bonding pads are bonded to the corresponding second bonding pads, and the first inter-metal dielectric layer is bonded to the second inter-metal dielectric layer.

In some embodiments, the second bonding pads comprising a dummy bonding pad, the dummy bonding pad is not electrically connected to any conductive device in the light-emitting diode wafer.

In some embodiments, the light-emitting diode wafer comprising an input/output terminal on the light-emitting diode wafer, wherein the input/output terminal is electrically connected to one of the second bonding pads, and the one of the second bonding pads has a size larger than that of the other second bonding pads.

In some embodiments, the light-emitting diode wafer comprising an input/output terminal on the light-emitting diode wafer, wherein the input/output terminal is electrically connected to several of the second bonding pads, and the several of the second bonding pads have substantially the same size as the other second bonding pads.

In some embodiments, the light-emitting diode wafer further comprising: micro-lens, covering the light-emitting diodes; or a quantum dot layer, covering the light-emitting diodes.

Embodiments of the present disclosure provide a semiconductor device, comprising: a light-emitting diode driver wafer, comprising: transistor devices; a first inter-metal dielectric layer, covering the transistor devices; and first bonding pads in the first inter-metal dielectric layer; and a light-emitting diode wafer, comprising: light-emitting diodes; a second inter-metal dielectric layer, covering the light-emitting diodes; and second bonding pads in the second inter-metal dielectric layer, wherein the light-emitting diode wafer is bonded to the light-emitting diode driver wafer through hybrid bonding, wherein the first bonding pads are bonded to the corresponding second bonding pads, and the first inter-metal dielectric layer is bonded to the second inter-metal dielectric layer.

In some embodiments, the second bonding pads comprising a dummy bonding pad, the dummy bonding pad is not electrically connected to any conductive device in the light-emitting diode wafer.

In some embodiments, the light-emitting diode wafer comprising an input/output terminal on the light-emitting diode wafer, wherein the input/output terminal is electrically connected to one of the second bonding pads, and the one of the second bonding pads has a size larger than that of the other second bonding pads.

In some embodiments, the light-emitting diode wafer comprising an input/output terminal on the light-emitting diode wafer, wherein the input/output terminal is electrically connected to several of the second bonding pads, and the several of the second bonding pads have substantially the same size as the other second bonding pads.

In some embodiments, the light-emitting diode wafer further comprising: micro-lens, covering the light-emitting diodes; or a quantum dot layer, covering the light-emitting diodes.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a cross-sectional view of a light-emitting diode wafer bonded to a light-emitting diode driver wafer according to some embodiments of the present disclosure.

FIGS. 2-4 illustrate cross-sectional views of intermediate stages in the fabrication of a semiconductor device according to some embodiments of the present disclosure.

FIG. 5 illustrates a cross-sectional view of a semiconductor device according to some embodiments of the present disclosure.

FIG. 6 illustrates a cross-sectional view of a semiconductor device according to some embodiments of the present disclosure.

FIG. 7 illustrates a top view of a semiconductor device according to some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

As used herein, “around”, “about”, “approximately”, or “substantially” may generally mean within 20 percent, or within 10 percent, or within 5 percent of a given value or range. Numerical quantities given herein are approximate meaning that the term “around”, “about”, “approximately”, or “substantially” can be inferred if not expressly stated. One skilled in the art will realize, however, that the values or ranges recited throughout the description are merely examples, and may be reduced or varied with the sown-scaling of the integrated circuits.

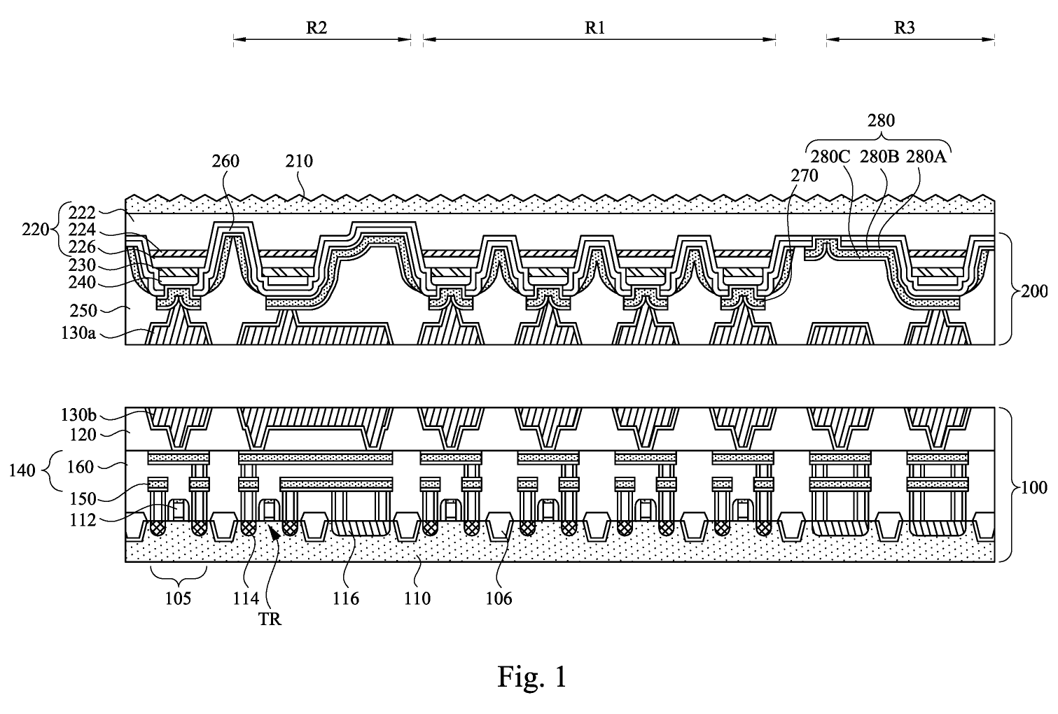

FIG. 1 illustrates a cross-sectional view of a light-emitting diode wafer (LED wafer) bonded to a light-emitting diode driver wafer (LED driver wafer) according to some embodiments of the present disclosure. Shown there is a light-emitting diode driver wafer (LED driver wafer) 100 and a light-emitting diode wafer (LED wafer) 200.

Referring first to the LED driver wafer 100, the LED driver wafer 100 includes a substrate 110 and a plurality of active regions 105 formed in the substrate 110. In some embodiments, the active regions 105 may be separated from each other by isolation structures 106. The isolation structures 106 may also be referred to as shallow trench isolation (STI) structures. A transistor device TR may be formed above the active regions 105, wherein the transistor device TR may include a gate structure 112 on the active region 105, and source/drain regions 114 located on both sides of the gate structure 112. In some embodiments, an inter-metal dielectric (IMD) layer 160 may be located above the substrate 110.

In some embodiments, the LED driver wafer 100 includes an interconnect structure 140 formed above the substrate 110 and electrically connected to the transistor device TR. In some embodiments, the interconnect structure 140 is formed within the IMD layer 160, wherein the interconnect structure 140 may include a plurality of metal lines and metal vias, which together form a functional circuit.

In some embodiments, the LED driver wafer 100 further includes a plurality of bonding pads 130b located in a redistribution layer (RDL) 120 and electrically connected to the interconnect structure 140. In certain embodiments, the top surface of the bonding pads 130b are coplanar with the top surface of the RDL layer 120. In some embodiments, a copper (Cu) material may be filled into the RDL layer 120 of the LED driver wafer 100 through an electrochemical plating (ECP) process to form the bonding pads 130b, which are in contact with the interconnect structure 140. In some embodiments, the bonding pads 130b may have different sizes in different regions. In some embodiments, the substrate 110 may include silicon (Si), other substrate material suitable for LED applications, or a combination thereof. In some embodiments, the RDL layer 120 may be an oxide layer.

Referring to the LED wafer 200. The LED wafer 200 includes a substrate 210 and an epitaxial structure 220 located below the substrate 210, which comprises various epitaxial layers 222, epitaxial layer 224 and epitaxial layer 226. The epitaxial structure 220 functions as a light-emitting diode (LED) and includes at least one n-type doped semiconductor layer and one p-type doped semiconductor layer configured to emit radiation. For example, the epitaxial layer 226 is a p-type doped GaN layer (p-GaN layer), the epitaxial layer 224 is a multiple quantum well (MQW) structure formed above the epitaxial layer 226, and the epitaxial layer 222 is an n-type doped GaN layer (n-GaN layer) formed above the epitaxial layer 224. In some embodiments, a buffer layer made of aluminum gallium nitride (AlGaN) and aluminum gallium nitride/aluminum nitride (AlGaN/AlN) superlattice may be formed between the epitaxial layer 222 (n-GaN layer) and the substrate 210. In some embodiments, the substrate 210 may comprise silicon (Si), other substrate materials suitable for LED applications, or a combination thereof.

The LED wafer 200 further includes a conductive film 230 formed below the epitaxial structure 220, an adhesion layer 240 formed below the conductive film 230, and an interlayer dielectric (ILD) layer 260 formed between an inter-metal dielectric (IMD) layer 250 and the stack formed by the adhesion layer 240, the conductive film 230, and the epitaxial structure 220. Additionally, a conductive structure 280 is formed below and in contact with the ILD layer 260. The conductive structure 280 includes a first metal layer 280A, a second metal layer 280B, and a third metal layer 280C, where the first metal layer 280A may serve as an adhesion or seed layer. In some embodiments, the conductive film 230 may include indium tin oxide (ITO). In some embodiments, the conductive structure 270 may be a p-type metal pad, and the conductive structure 280 may be an n-type metal pad. Below each conductive structure 270 (p-metal), a bonding pad 130a is formed within the IMD layer 250 of the LED wafer 200 by filling copper (Cu) material using an ECP process, and is in contact with the conductive structure 270. Furthermore, the bottom surface of the bonding pad 130a is coplanar with the bottom surface of the IMD layer 250. In some embodiments, bonding pads 130a may have different sizes in different regions. Each bonding pad 130a in the LED wafer 200 corresponds to a bonding pad 130b in the LED driver wafer 100, and bonding pads 130b and bonding pads 130a are aligned with each other. In some embodiments, the IMD layer 250 may be an oxide layer.

As shown in FIG. 1, the LED driver wafer 100 and the LED wafer 200 are bonded together through hybrid bonding. Hybrid bonding includes both metal-to-metal bonding and dielectric-to-dielectric bonding. Metal-to-metal bonding (e.g., diffusion bonding) can occur between multiple bonding pads 130a and multiple bonding pads 130b. Dielectric-to-dielectric bonding can occur between the RDL layer 120 and the IMD layer 250, allowing the RDL layer 120 and the IMD layer 250 to be in direct contact. The plurality of bonding pads 130a and bonding pads 130b serve as a plurality of mating pads and may include redistribution layers (RDLs). In some embodiments, the dielectric-to-dielectric bonding is oxide-to-oxide bonding.

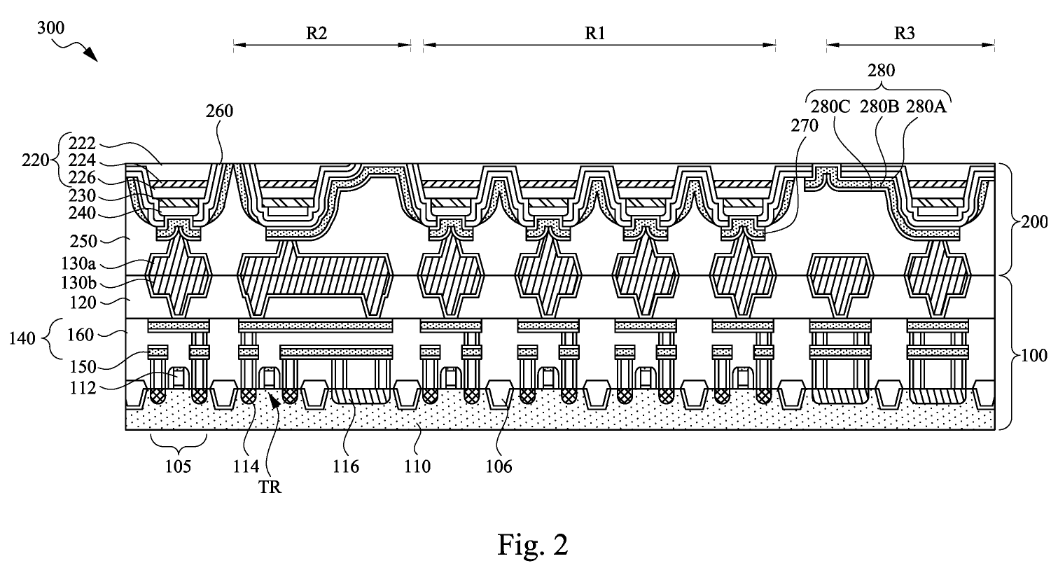

As shown in FIG. 2, after the LED driver wafer 100 is bonded to the LED wafer 200 via hybrid bonding, a semiconductor device 300 is formed. Then, through a planarization process, such as a grinding process, chemical mechanical polishing (CMP) process, or any other suitable process, potions of the substrate 210, the epitaxial layer 222, and the ILD layer 260 of the LED wafer 200 are removed until the first metal layer 280A is exposed. In some embodiments, the substrate 210 of the LED wafer 200 is completely removed after the planarization process.

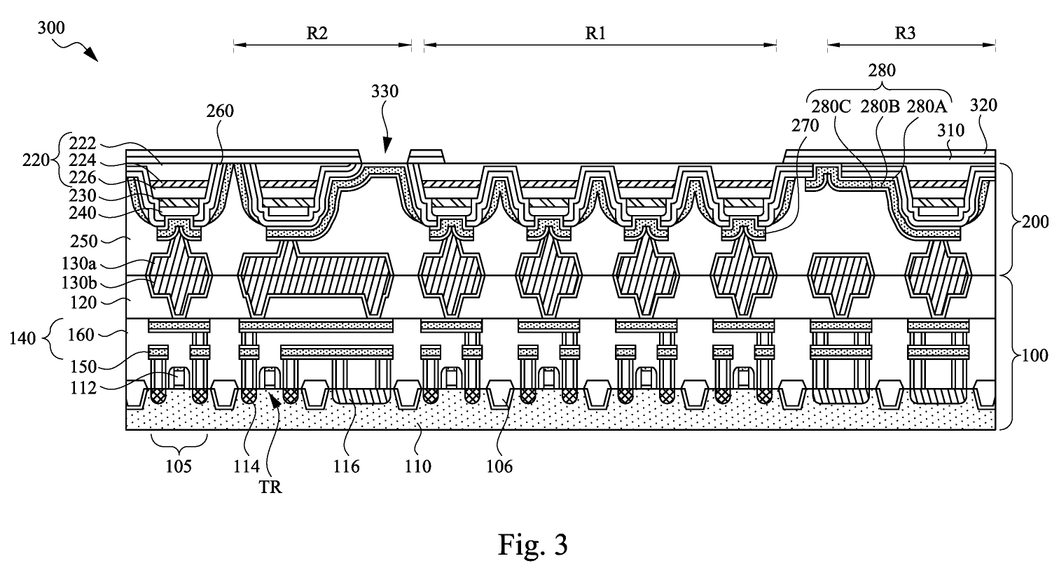

Referring to FIG. 3, a passivation layer 310 is deposited on one side of the semiconductor device 300 (i.e., over the epitaxial layer 222 and the exposed first metal layer 280A), and both passivation layer 310 and passivation layer 320 are deposited. Subsequently, the passivation layer 310 and the passivation layer 320 may be patterned to form a plurality of openings 330, where at least one opening 330 exposes the first metal layer 280A and at least one opening exposes the LED array. In some embodiments, the passivation layer 310 and the passivation layer 320 may be made of different dielectric materials. For example, the passivation layer 310 may be a nitride layer, while the passivation layer 320 may be an oxide layer.

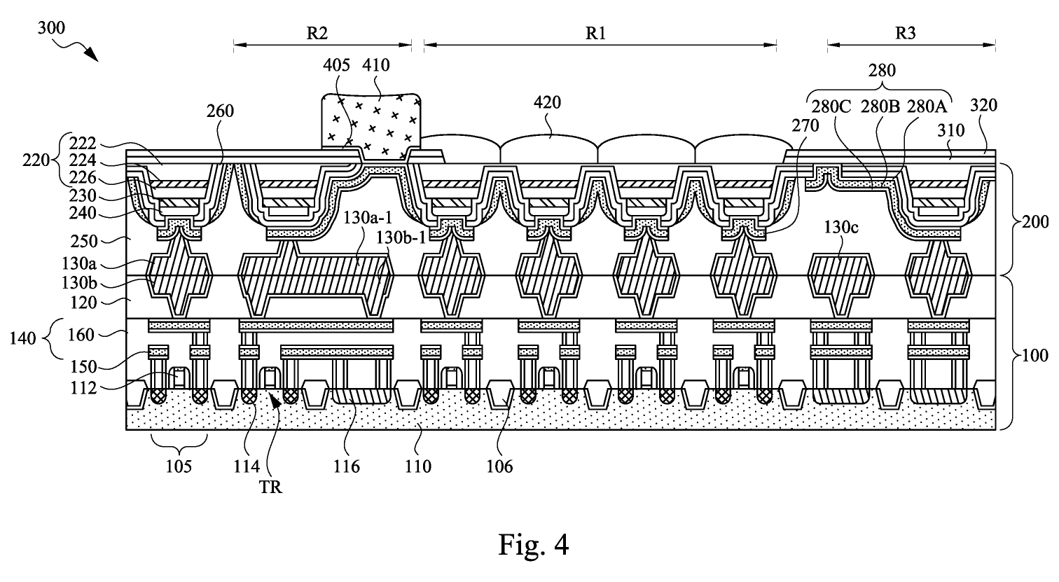

Referring to FIG. 4, the semiconductor device 300 includes an LED array region R1, an input/output (I/O) region R2, and a ground region R3. A layer of under-bump metal (UBM) layer 405 is formed within the opening 330 in the I/O region R2. The UBM layer 405 may also extend onto the top surface of the passivation layer 320. A bump 410 is formed above the UBM layer 405, thereby filling the openings 330 in the I/O region with the UBM layer 405 and the bump 410. The bump 410 is electrically coupled to the underlying conductive structure 280. In some embodiments, a plurality of micro-lenses 420 is formed above the epitaxial layer 222 of the LED array, which can enhance light emission efficiency and reduce the emission angle, as shown in FIG. 4.

In certain embodiments, the LED array region R1 includes a plurality of light-emitting diodes (i.e., epitaxial structures 220) arranged in an array configuration. Each LED may be electrically connected to a corresponding transistor device TR via the conductive structure 270, bonding pad 130a, bonding pad 130b, and interconnect structure 140. The transistor device TR can serve as the driving element for each individual light-emitting diode. The input/output region R2 may include bump 410, which function as external input/output terminals. The bump 410 can be electrically connected to the doped regions 116 in the substrate 110 through the conductive structure 280, bonding pad 130a, bonding pad 130b, and interconnect structure 140.

In FIG. 4, the input/output region R2 of the semiconductor device 300 includes bonding pads 130a-1 and 130b-1 that are electrically connected to bump 410, wherein bonding pad 130a-1 has a larger size compared to other bonding pads 130a, and bonding pad 130b-1 has a larger size compared to other bonding pads 130b. Since the input/output region R2 may experience higher input voltages, setting larger-sized bonding pads 130a-1 and 130b-1 helps improve the electrical performance of the device.

On the other hand, the LED wafer 200 also includes a dummy bonding pad 130c, which may not have a circuit function. In other words, the dummy bonding pad 130c is not electrically connected to any conductive element in the LED wafer 200. The dummy bonding pad 130c not only helps with the connection between the LED driver wafer 100 and the LED wafer 200, but also prevents load effects during planarization processes (e.g., CMP process).

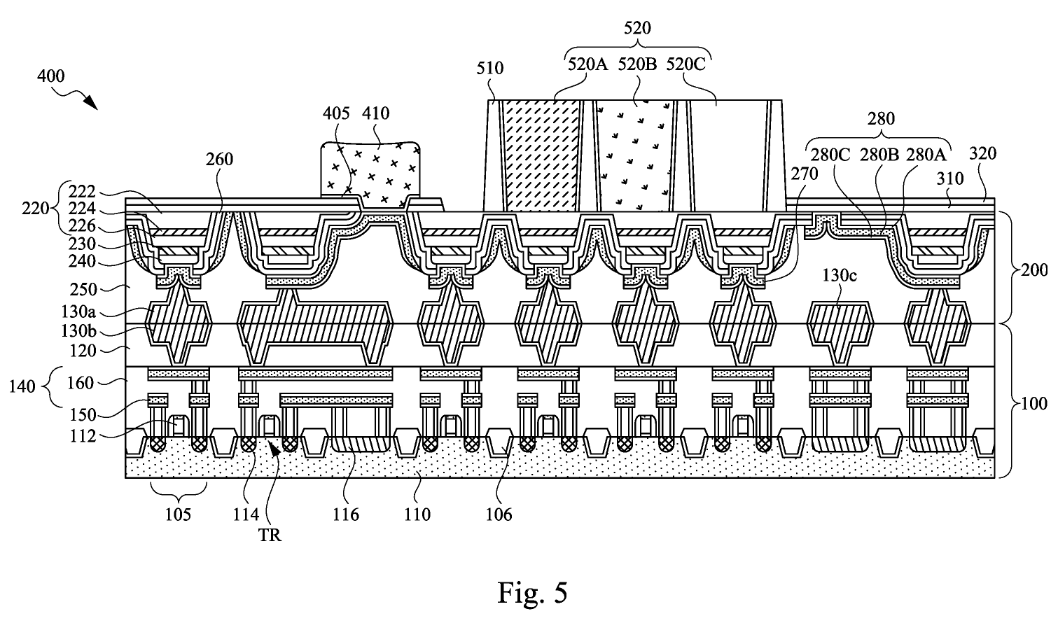

FIG. 5 illustrates a cross-sectional view of a semiconductor device according to some embodiments of the present disclosure. FIG. 5 is similar to FIG. 4, so similar components will use the same reference numerals, and thus, their description details are omitted. FIG. 5 illustrates a semiconductor device 400, wherein a quantum dot (QD) layer 520 is located above the LED array region R1 of the semiconductor device 400, which consists of light-emitting diodes (i.e., epitaxial structure 220). The QD layer 520 includes quantum dot material 520A that generates red light wavelengths, quantum dot material 520B that generates green light wavelengths, or light scattering material 520C made of undoped quantum dot material, with the quantum dot material 520A, quantum dot material 520B, and light scattering material 520C corresponding to individual light-emitting diodes. In certain embodiments, the QD layer 520 can be formed using inkjet printing technology (IJP). In embodiments where the light emitted by the LED die is blue, quantum dot material 520A can convert the blue wavelength of the LED die into a red wavelength, generating red light. Quantum dot material 520B can covert the blue wavelength of the LED die into a green wavelength, generating green light. Blue light can directly pass through the light scattering material 520C.

As shown in FIG. 5, the partition wall 510 is located around and surrounds the QD layer 520. In some embodiments, the partition wall 510 can reflect light and alter its path in order to reduce light mixing between the QD layer 520 of the individual LED die, and to enhance light extraction efficiency. In some embodiments, the partition wall 510 can be made of non-absorptive inorganic materials with a low refractive index (e.g., silicon oxide), low-refractive-index, non-absorptive polymer materials, or metals.

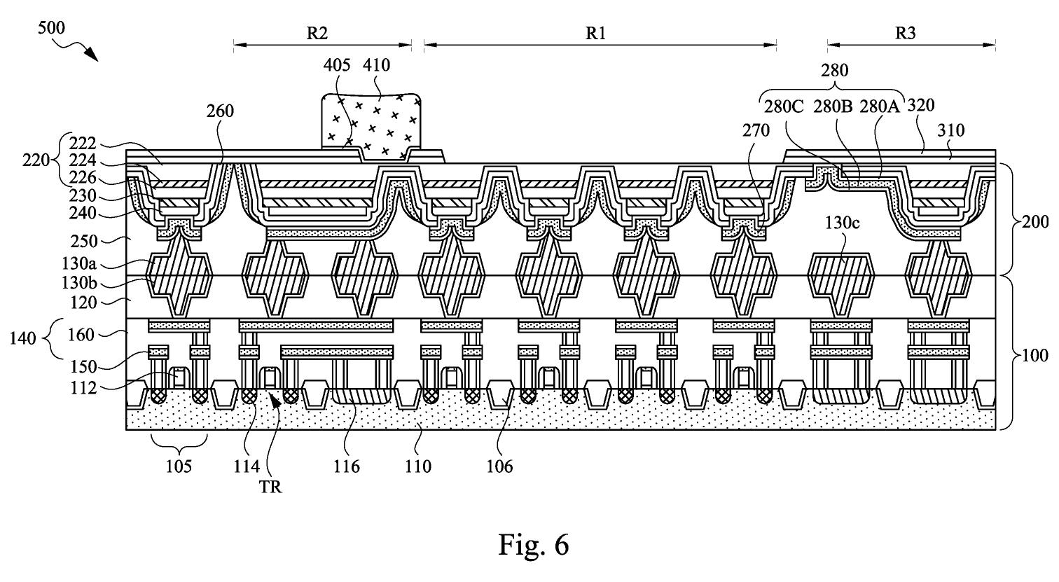

FIG. 6 shows a cross-sectional view of the semiconductor device 500 according to some embodiments of the present disclosure. FIG. 6 is similar to FIG. 4, so similar components will use the same reference numerals, and the associated details will not be repeated. FIG. 6 illustrates a semiconductor device 500. In semiconductor device 500, each bonding pad 130a has a substantially identical size, and each bonding pad 130b has a substantially identical size. In certain embodiments, the size difference between each bonding pad 130a is less than about 10%, and the size difference between each bonding pad 130b is less than about 10%. Specially, bonding pad 130a-1 in FIG. 4 can be split into multiple bonding pads 130a with the same size, and bonding pad 130b-1 in FIG. 4 can be split into multiple bonding pads 130b with the same size. For example, for the sake of clarity, FIG. 6 illustrates only two bonding pads 130a, split from bonding pad 130a-1 of FIG. 4, and two bonding pads 130b, split from bonding pad 130b-1 of FIG. 4. It should be understand that bonding pad 130a-1 in FIG. 4 can be split into two or more bonding pads 130a, and bonding pad 130b-1 in FIG. 4 can be split into two or more bonding pads 130b. This configuration helps promote uniformity during the hybrid bonding process.

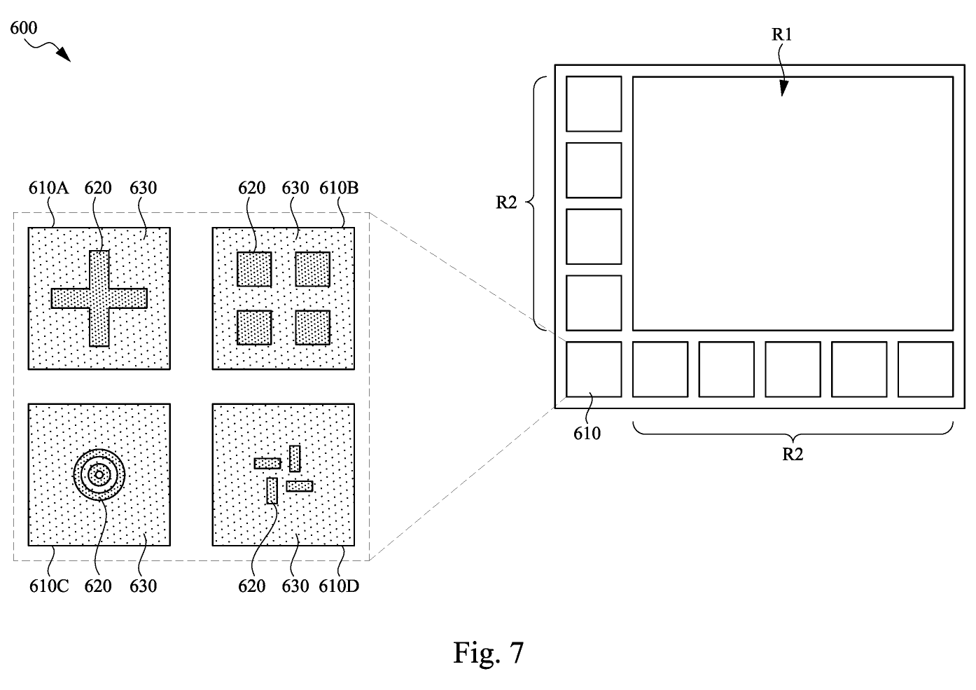

FIG. 7 shows a top view of the layout design of a semiconductor device 600 according to some embodiments of the present disclosure. FIG. 7 illustrates a semiconductor device 600, which may be similar to the LED wafer 200 described above and includes an LED array region R1, an input/output region R2, and an alignment mark region 610. The alignment mark region 610 may have different patterns, such as alignment mark regions 610A, alignment mark regions 610B, alignment mark regions 610C, or alignment mark regions 610D. Each of the alignment mark regions 610A, alignment mark regions 610B, alignment mark regions 610C, and alignment mark regions 610D may include alignment marks 620 and dummy patterns 630. In the semiconductor device 600, both the alignment marks 620 and dummy patterns 630 are composed of multiple bonding pads (also referred to as metal features) of the same size. In certain embodiments, the alignment marks 620 have specific shapes, such as cross, ring, or rectangular, etc. In some embodiments, the bonding pad density in the dummy pattern 630 is lower than that in the alignment mark 620. That is, the alignment marks 620, having a higher density of bonding pads, can form a more distinct pattern in a top view, which helps alignment tools identify them during the wafer alignment process. Additionally, dividing the alignment marks 620 into multiple small metal features, along with placing similar small metal features as dummy patterns 630 around the alignment marks 620, helps improve uniformity during processes such as bonding or planarization. In certain embodiments, the alignment mark region 610 may be located on the LED wafer 200 or on the LED driver wafer 100, and may be coplanar with the bonding pads (e.g., bonding pad 130a and bonding pad 130b).

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method for forming a semiconductor device, comprising:
providing a light-emitting diode driver wafer, comprising:
transistor devices;
a first inter-metal dielectric layer, covering the transistor devices; and
first bonding pads in the first inter-metal dielectric layer;
providing a light-emitting diode wafer, comprising:
light-emitting diodes;
a second inter-metal dielectric layer, covering the light-emitting diodes; and
second bonding pads in the second inter-metal dielectric layer; and
bonding the light-emitting diode driver wafer to the light-emitting diode wafer through hybrid bonding, wherein the first bonding pads are bonded to the corresponding second bonding pads, and the first inter-metal dielectric layer is bonded to the second inter-metal dielectric layer.

2. The method of claim 1, wherein the second bonding pads comprising a dummy bonding pad, the dummy bonding pad is not electrically connected to any conductive device in the light-emitting diode wafer.

3. The method of claim 1, wherein:
the light-emitting diode wafer comprising an input/output terminal on the light-emitting diode wafer, wherein the input/output terminal is electrically connected to one of the second bonding pads, and the one of the second bonding pads has a size larger than that of the other second bonding pads.

4. The method of claim 1, wherein:
the light-emitting diode wafer comprising an input/output terminal on the light-emitting diode wafer, wherein the input/output terminal is electrically connected to several of the second bonding pads, and the several of the second bonding pads have substantially the same size as the other second bonding pads.

5. The method of claim 1, wherein the light-emitting diode wafer further comprising:
micro-lenses, covering the light-emitting diodes; or
a quantum dot layer, covering the light-emitting diodes.

6. A semiconductor device, comprising:
a light-emitting diode driver wafer, comprising:
transistor devices;
a first inter-metal dielectric layer, covering the transistor devices; and
first bonding pads in the first inter-metal dielectric layer; and
a light-emitting diode wafer, comprising:
light-emitting diodes;
a second inter-metal dielectric layer, covering the light-emitting diodes; and
second bonding pads in the second inter-metal dielectric layer, wherein the light-emitting diode wafer is bonded to the light-emitting diode driver wafer through hybrid bonding, wherein the first bonding pads are bonded to the corresponding second bonding pads, and the first inter-metal dielectric layer is bonded to the second inter-metal dielectric layer.

7. The semiconductor device of claim 6, wherein the second bonding pads comprising a dummy bonding pad, the dummy bonding pad is not electrically connected to any conductive device in the light-emitting diode wafer.

8. The semiconductor device of claim 6, wherein:
the light-emitting diode wafer comprising an input/output terminal on the light-emitting diode wafer, wherein the input/output terminal is electrically connected to one of the second bonding pads, and the one of the second bonding pads has a size larger than that of the other second bonding pads.

9. The semiconductor device of claim 6, wherein:
the light-emitting diode wafer comprising an input/output terminal on the light-emitting diode wafer, wherein the input/output terminal is electrically connected to several of the second bonding pads, and the several of the second bonding pads have substantially the same size as the other second bonding pads.

10. The semiconductor device of claim 6, wherein the light-emitting diode wafer further comprising:
micro-lenses, covering the light-emitting diodes; or
a quantum dot layer, covering the light-emitting diodes.
